(19) United States
(12) Patent Application Publication
(10) Pub. No.: US 2011/0002176 A1
(43) Pub. Date: Jan. 6, 2011

(54) SEMICONDUCTOR MEMORY DEVICE

(76) Inventor: Tae-Sig CHANG, Gyeonggi-do (KR)

Correspondence Address: IP & T GROUP LLP, 7700 Little River Turnpike, Suite 207, Annandale, VA, 22003, US

(21) Appl. No.: 12/615,928

(22) Filed: Nov. 10, 2009

(30) Foreign Application Priority Data
Jul. 3, 2009 (KR) 10-2009-0060643

(51) Int. Cl. G11C 7/10; G11C 17/16; G11C 7/00

(52) U.S. Cl. 365/189.05; 365/225.7; 365/189.11

(57) ABSTRACT

A semiconductor memory device includes a repair node; a fuse, one side of which is coupled to the repair node; a pull-down unit configured to selectively transfer a ground voltage to the repair node; a pull-up unit configured to selectively transfer a driving voltage to another side of the fuse; a latch unit configured to latch a signal at the repair node; and a switch unit coupled between the latch unit and the repair node and configured to selectively transfer the signal from the repair node to the latch unit.

### CROSS-REFERENCE TO RELATED APPLICATIONS

The present application claims priority of Korean Patent Application No. 10-2009-0060643, filed on Jul. 3, 2009, which is incorporated herein by reference in its entirety.

### BACKGROUND OF THE INVENTION

Exemplary embodiments of the present invention relate to a semiconductor memory device, and more particularly, to a fuse of a semiconductor memory device.

If even a single defect occurs during the fabrication of a semiconductor memory device, the device may not function properly as a memory, and thus becomes defective. Although the defect occurs only in a cell of a memory, the overall device that includes the defective memory cell (“cell”) may need to be discarded, which gives inefficient yield.

Now, the inefficiency in yields may be resolved by forming some spare cells inside a memory device, and replacing a defective cell with a spare cell to repair the overall memory. A repair operation using spare cells is generally performed by pre-installing a spare word line prepared to be replaced with a normal word line and/or a spare bit line prepared to be replaced with a normal bit line. Next, a normal word line, or a normal bit line which includes a defective cell, is replaced with the spare word line or the spare bit line. To be specific, when a defective cell is detected by a test after fabrication of a wafer, a program for changing an address of the defective cell with an address of a spare cell may be executed inside an internal circuit. Therefore, when the memory with the defective cell is used, and an address signal indicating the defective cell is input, the data of the spare cell (that replaces the defective cell) is accessed.

A widely used address changing method uses a program to change the path of an address by firing a fuse with laser beam to blow the fired fuse. For example, a typical semiconductor memory device includes a fuse unit for changing an address path by irradiating a fuse with a laser and blowing the fuse. A fuse unit includes a plurality of fuse sets, each of which can replace one address path. The number of fuse sets in a fuse unit depends on the number of spare word lines or spare bit lines that are provided and based on the margin area of a semiconductor memory device. Each fuse set may include a plurality of fuses for addresses, and an address path is replaced by selectively blowing the fuses for addresses.

A fuse unit may be provided with multiple fuses and a fuse guard ring for protecting an internal circuit from impurities penetrating the internal circuit through a fuse region. However, the metal around a fuse may be corroded due to a voltage applied to the fuse after the fuse is blown.

### SUMMARY OF THE INVENTION

An embodiment of the present invention is directed to a semiconductor memory device that can protect fuses from being corroded.

In accordance with an embodiment of the present invention, a semiconductor memory device includes a repair node; a fuse, one side of which is coupled to the repair node; a pull-down unit configured to selectively transfer a ground voltage to the repair node; a pull-up unit configured to selectively transfer a driving voltage to another side of the fuse; a latch unit configured to latch a signal at the repair node; and a switch unit coupled between the latch unit and the repair node and configured to selectively transfer the signal from the repair node to the latch unit.

The switch unit and the pull-up unit may be activated for a substantially same duration.

The latch unit may include two inverters that are cross-coupled to each other.

The switch unit may include a MOS transistor.

The pull-up unit may include a PMOS transistor receiving a first power-up signal through its gate.

The MOS transistor of the switch unit may receive a second power-up signal whose phase is opposite to a phase of the first power-up signal through its gate.

The pull-down unit may include an NMOS transistor receiving the first power-up signal through its gate.

The fuse may be formed of at least one layer selected from the group consisting of a titanium nitride layer, a copper layer, and an aluminum layer.

### BRIEF DESCRIPTION OF THE DRAWINGS

FIG. 1 is a cross-sectional view illustrating a fuse of a semiconductor memory device, according to an embodiment of the present invention.

FIG. 2 is a circuit diagram illustrating a fuse unit of a semiconductor memory device, according to an embodiment of the present invention.

FIGS. 3A and 3B are cross-sectional views showing oxidation caused around a fuse by the operation of the fuse unit illustrated in FIG. 2, according to an embodiment of the present invention.

FIG. 4 is a circuit diagram illustrating a fuse unit of a semiconductor memory device, according to an embodiment of the present invention.

FIG. 5 depicts waveforms according to the operation of the semiconductor memory device illustrated in FIG. 4, according to an embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

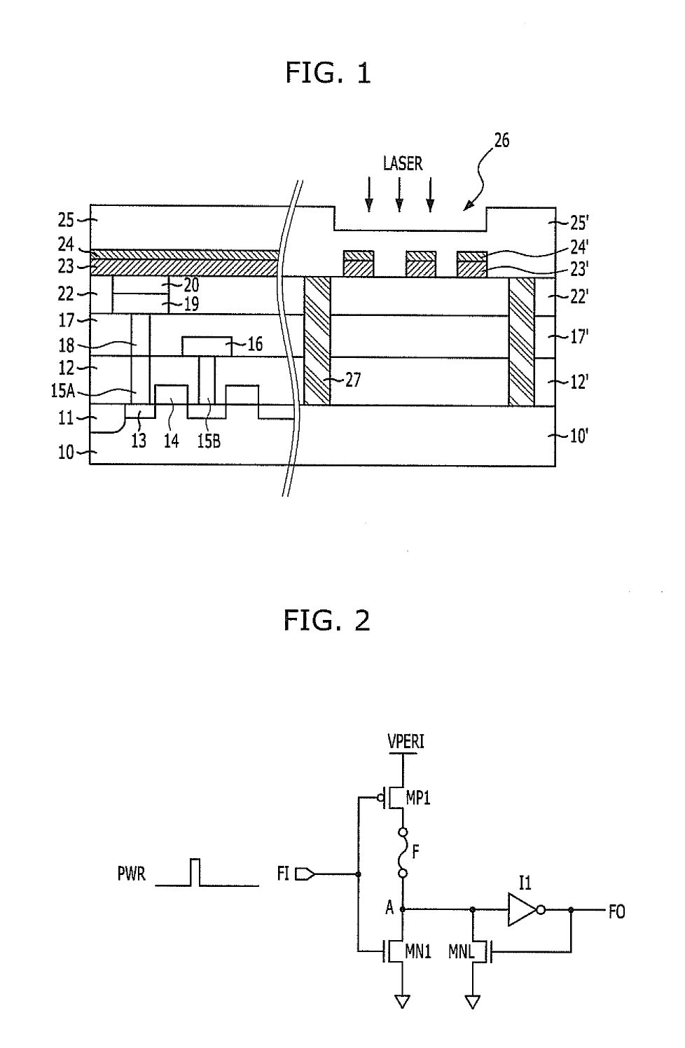

FIG. 1 is a cross-sectional view illustrating a fuse of a semiconductor memory device, according to an embodiment of the present invention. The left part of the drawing shows a cross section of a cell region, whereas the right part of the drawing shows a fuse region.

Referring to FIG. 1, a cell region of the semiconductor memory device includes an isolation layer 11, an active region 13, a gate pattern 14, a first storage node contact plug 15A, a second storage node contact plug 18, a bit line contact plug 15B, a bit line 16, inter-layer dielectric layers 12, 17, 22 and 25, and a capacitor including a lower plate electrode 19, a dielectric thin film 20 and a upper plate electrode 23 and 24 over a substrate 10. The upper plate electrode 23 and 24 includes a polysilicon layer 23 and a titanium nitride (TiN) layer 24.

A fuse region of the semiconductor memory device is provided with inter-layer dielectric layers 12′, 17′ and 22′, a fuse including a polysilicon layer 23′, and a TiN layer 24′, an inter-layer dielectric layer 25′ formed in the upper portion of the fuse, and a guard ring 27 for minimizing moisture permeation over a substrate. Also, a fuse box 26 is formed by removing the inter-layer dielectric layer 25′ in the upper portion of the fuse by a predetermined thickness, which facilitates blowing of the fuse during a repair process. The inter-layer dielectric layers 12′, 17′ and 22′ and the fuse 23′ and 24′ do not need to be formed separately and may be formed together when the inter-layer dielectric layers 12, 17 and 22 in the cell region and the upper plate electrode 23 and 24 for the capacitor are formed respectively. As aforementioned, the fuse is formed to repair a failure in a semiconductor memory device. Generally, the fuse is not formed through a separate process, but it is formed using a conductive layer, e.g., a polysilicon layer, forming bit lines and/or word lines in a cell region.

However, as semiconductor devices become highly integrated, the overall dimensions of the semiconductor devices may become larger. In order to form a fuse with a relatively smaller structural dimensions, where the fuse includes word lines and/or bit lines, one or more inter-layer dielectric layers may need to be removed to form a fuse box in a separate step, which adds extra complicacy to the whole process. To resolve this problem, a conductive layer formed in the upper portion of a semiconductor device may be also used as a fuse line. To be specific, a metal line or a conductive layer for forming a plate electrode of a capacitor may be also used as a fuse line. The fuse 23′ and 24′ illustrated in FIG. 1 is formed of a conductive layer for forming the plate electrodes 23 and 24 of a capacitor formed in a cell region. For example, the height of the semiconductor memory device from a substrate to the uppermost layer may be large that a fuse is formed using a metal line layer.

FIG. 2 is a circuit diagram illustrating a fuse unit of a semiconductor memory device, according to an embodiment of the present invention.

Referring to FIG. 2, the fuse unit includes a first NMOS transistor MN1 and a PMOS transistor MP1, a fuse F, an inverter I1, and a second NMOS transistor MNL. The inverter I1 and the second NMOS transistor MNL form a latch unit. The fuse F is a portion to be blown by laser irradiation. A power-up signal PWR is input to an input end FI of the fuse unit. The power-up signal PWR is activated when power is input to a semiconductor memory device and stabilized at a predetermined voltage level. Upon the activation of the power-up signal PWR, it can be seen that a voltage needed for internal operation is applied to the semiconductor memory device.

When the power-up signal PWR is input at a logic low level, the PMOS transistor MP1 is turned on and a voltage of a repair node A is at a logic high level. When the voltage of the repair node A is at the logic high level, an output signal FO of the inverter I1 transitions to a logic low level. In this state, when the fuse F is blown by being irradiated with a laser and the power-up signal PWR transitions to a logic high level, the first NMOS transistor MN1 is turned on, and thus the signal of the repair node A transitions to a logic low level while the output signal FO of the inverter I1 transitions to a logic high level. When the output signal FO of the inverter I1 transitions to a logic high level, input and output ends of the inverter I1 are latched through the MOS transistor MNL. Once the fuse F is blown, when the voltage level of the power-up signal PWR goes back to a logic low level, the voltage level of the repair node A does not become a logic high level even if the PMOS transistor MP1 is turned on.

If the fuse F is not blown, the voltage level of the repair node A transitions to a logic high level and thus the output signal of the inverter I1 becomes a logic low level.

Therefore, the voltage level of the output signal FO is different depending on whether the fuse F is blown, and whether the power-up signal PWR is input. A decision to replace a defective cell with a spare cell may be made based on the voltage level of the output signal FO. An actual semiconductor memory device may include as many fuses as the number of bits of an address to be compared, although a semiconductor device can also have a higher or lower number of fuses, as desired. A replaced address may be indicated by selectively blowing the fuses of each fuse unit.

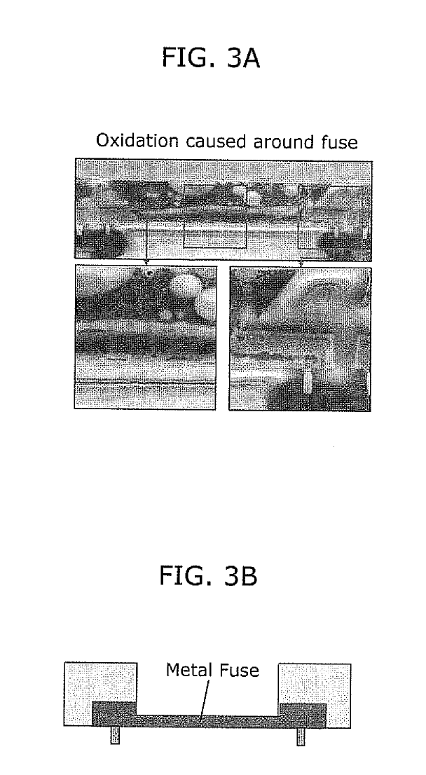

FIGS. 3A and 3B are cross-sectional views showing oxidation around a fuse caused by the operation of the fuse unit illustrated in FIG. 2, according to an embodiment of the present invention. FIG. 3A is an electronic microscopic picture of a fuse unit, and FIG. 3B shows a cross section of a fuse, according to an embodiment of the present invention.

Most of an insulation layer in the upper portion of a fuse unit is removed so that the fuse unit is irradiated with a laser during a test process. When fuses are formed from metal and moisture permeates into the fuse unit, the fuses and the metal layers in the peripheral region of the fuses may become corroded. A guard ring surrounds the peripheral region of the fuses with a first metal line layer, a second metal line layer, a first contact, and a second contact. Since the fuse unit forms the guard ring of a metal layer around the fuses, the metal layer itself may be corroded. Particularly, as the voltage difference between both ends of a fuse becomes larger, the severity of corrosion of the metal layer gets worse. Therefore, it is advantageous to reduce the voltage difference.

As illustrated in FIG. 3A, since a voltage difference is induced between the fuse and the guard ring for protecting the peripheral region of the fuse unit from moisture permeation, the corrosion of the fuse unit may worsen. When the fuses are corroded, they are swollen, and the swollen fuses may cause a protective layer to be cracked, which leads to corrosion of a metal layer in an adjacent circuit.

The corrosion of a metal fuse, which is also referred to as anodization of a metal fuse, can occur under various levels of humidity, temperature, and voltage difference between the two ends (i.e., sides) of the fuse. In a conventional circuit, when a fuse is blown, the voltage level of one side of the blown fuse is raised to the voltage level of a peripheral region while the voltage level of the other side comes down to a ground voltage level. Since the voltage difference between the two sides of the fuse may easily become large, the fuse may readily corrode.

As semiconductor memory devices are developed to be faster and highly integrated, the number of line layers used therein may be increased. Also, cell capacitors may be realized stereoscopically to increase the capacitance of a capacitor in a unit cell of a semiconductor memory device. As a result, the thickness of an inter-layer dielectric layer between a gate pattern and a metal line is increased. Therefore, a metal layer over the gate pattern may be used as a fuse, instead of just using the gate pattern.

To increase the capacitance of a capacitor in a unit cell, a plate electrode of the capacitor is formed of a metal layer such as a titanium nitride layer, instead of a typical polysilicon layer. The fuse may also be formed using a metal layer as well instead of a polysilicon layer (which has been conventionally used.)

Since the fuses are formed of a metal layer, such as a titanium nitride layer, an aluminum layer, and/or a copper layer, moisture may permeate into the fuse unit during a reliability test, in which bias is applied in a high-temperature and high-humidity environment and thereby the fuses may be corroded. For example, the reliability test may be a highly accelerated storage test (HAST) performed at 130° C. with a humidity of 85% @VCC, a temperature humidity bias (THB) test performed at 85° C. with a humidity of 85% @VCC, or a Pressure Cook Test (PCT), although other conditions and/or tests are contemplated. Here, “@VCC” means “at a power supply voltage (VCC)”. When the fuses are corroded, the address changed during a repair process may not be properly recognized in a semiconductor memory device. To minimizing this from occurring and to protect the fuse from the moisture permeation, a nitride layer may be additionally deposited over the fuse unit, or a polysilicon layer may be formed in the upper portion of the fuses after the laser irradiation. This method, however, increases the steps of a fabrication process and may not perfectly protect the fuses from moisture permeation through a cross section of the blown fuse.

Moreover, when a voltage is applied to a metal fuse, oxidation may occur many times faster than when a fuse is formed from a typical material, which is not metal. The metal fuse may also be corroded if a voltage is applied to the fuse in a high-temperature and high-humidity environment. After the fuse is blown, the PMOS transistor MP1 maintains a turn-on state and a ground voltage is applied to another adjacent fuse. Thus, a voltage difference is caused between the fuses (i.e., the metal fuse and the adjacent fuse.) When moisture permeates between the fuses, the fuses become corroded and oxidized, which lead to a failure.

Thus, the fuse unit may basically block the occurrence of a voltage difference between adjacent fuses by checking whether a fuse is blown or not during a power-up operation or an active-mode operation, and cutting off a voltage applied to a fuse after data is latched. A semiconductor memory device employing the fuse unit described herein can have an improved product reliability even in a high-temperature and high-humidity environment such as HAST or THB tests.

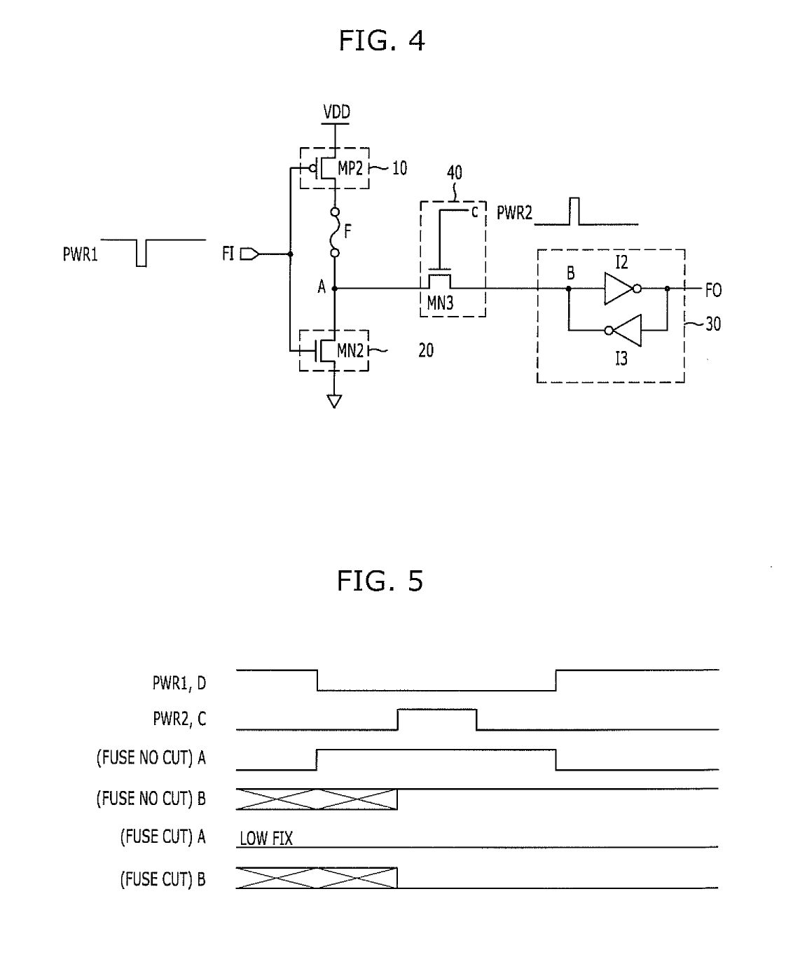

FIG. 4 is a circuit diagram illustrating a fuse unit of a semiconductor memory device, according to an embodiment of the present invention.

Referring to FIG. 4, the semiconductor memory device includes a fuse F, one side of which is coupled to a repair node A, a pull-down unit 20, a pull-up unit 10, a latch unit 30, and a switch unit 40. The pull-down unit 20 selectively transfers a ground voltage to the repair node A. The pull-up unit 10 selectively transfers an operation voltage to the other side of the fuse F. The latch unit 30 latches a signal at the repair node A. The switch unit 40 is coupled between the latch unit 30 and the repair node A, and selectively transfers the signal from the repair node A to the latch unit 30. A supply voltage VDD is used as a driving voltage, but it is possible to use an internal voltage such as a peripheral circuit voltage VPERI.

The switch unit 40 and the pull-up unit 10 may be activated substantially at the same time. Also, the latch unit 30 may include two inverters I2 and I3, which are cross-coupled to each other. The switch unit 40 includes a first NMOS transistor MN3. The first NMOS transistor has a source and a drain coupled between the repair node A and the latch unit 30, as shown in FIG. 4. The pull-up unit 10 includes a PMOS transistor MP2 receiving a first power-up signal PWR1 through a gate (i.e., via FI). Also, a second power-up signal PWR2 having an opposite phase to the first power-up signal PWR1 is input to the gate of the first NMOS transistor MN3 of the switch unit 40 (i.e., via C.)

The pull-down unit 20 includes a second NMOS transistor MN2 receiving the first power-up signal PWR1 through its gate (i.e., via FI.) Also, the fuse F may use one or more of a titanium nitride layer, a copper layer, and/or an aluminum layer.

FIG. 5 depicts waveforms according to the operation of the semiconductor memory device illustrated in FIG. 4, according to an embodiment of the present invention.

Referring to FIG. 5, when the fuse F is not blown (that is, when it is not cut), and the voltage level of the first power-up signal PWR1 becomes low, the voltage level of the node A becomes high and the first NMOS transistor MN3 of the switch unit 40 is turned on according to the second power-up signal PWR2. Concurrently, a signal from the node A is transferred to a node B to be stored in the latch unit 30. When the first NMOS transistor MN3 of the switch unit 40 is turned off according to the second power-up signal PWR2, and the second PMOS transistor MP2 of the pull-up unit 10 is turned off according to the first power-up signal PWR1, supply voltages supplied to both ends of the fuse F are cut off.

When the fuse F is blown, the node A maintains the low level of voltage since high-level voltage cannot be applied to the node A, even if the second PMOS transistor MP2 of the pull-up unit 10 is turned on. When the first NMOS transistor MN3 of the switch unit 40 is turned on in response to the second power-up signal PWR2, the voltage of the node B is latched at a low level and the latch unit 30 stores the low level voltage. When the first NMOS transistor MN3 of the switch unit 40 is turned off in response to the second power-up signal PWR2, and the second PMOS transistor MP2 of the pull-up unit 10 is turned off in response to the first power-up signal PWR1, no voltage is applied to either end (i.e., side) of the fuse F.

The fuse unit of the memory device, in accordance with the embodiments described herein, induces no voltage at either end of the fuse F by using the first and second power-up signals PWR1 and PWR2 with an opposite phase to each other and the first NMOS transistor MN3 of the switch unit 40. To be specific, a voltage is applied to the fuse F if a signal is received. Otherwise, a ground voltage is applied to the fuse F or the fuse F floats.

With the first and second power-up signals PWR1 and PWR2 applied to the fuse unit of the semiconductor memory device in accordance with the embodiments described herein, it is possible to improve the reliability of a product in a high-temperature and high-humidity environment without an increase in production cost that may be caused by the presence of an additional step. Therefore, the technology in accordance with the embodiments described herein can protect the area around a fuse from being corroded in a high-temperature and high-humidity environment. When a semiconductor memory device is fabricated in accordance with the embodiments described herein, the product reliability of the semiconductor memory device can be improved.

The semiconductor memory device may thus protect a fuse region from being corroded even in a high-temperature and high-humidity environment. Thus, it is possible to improve the product reliability of a semiconductor memory device.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device, comprising:
a repair node;
a fuse, one side of which is coupled to the repair node;
a pull-down unit configured to selectively transfer a ground voltage to the repair node;
a pull-up unit configured to selectively transfer a driving voltage to another side of the fuse;
a latch unit configured to latch a signal at the repair node; and
a switch unit coupled between the latch unit and the repair node and configured to selectively transfer the signal from the repair node to the latch unit.

2. The semiconductor memory device of claim 1, wherein the switch unit and the pull-up unit are activated for a substantially same duration.

3. The semiconductor memory device of claim 1, wherein the latch unit includes two inverters that are cross-coupled to each other.

4. The semiconductor memory device of claim 1, wherein the switch unit includes a metal-oxide semiconductor (MOS) transistor coupled to a source and a drain that are coupled between the repair node and the latch unit.

5. The semiconductor memory device of claim 1, wherein the pull-up unit includes a P-type MOS (PMOS) transistor receiving a first power-up signal through its gate.

6. The semiconductor memory device of claim 5, wherein the switch unit includes a MOS transistor receiving a second power-up signal whose phase is opposite to a phase of the first power-up signal through its gate.

7. The semiconductor memory device of claim 5, wherein the pull-down unit includes an N-type MOS (NMOS) transistor receiving the first power-up signal through its gate.

8. The semiconductor memory device of claim 1, wherein the fuse is formed of at least one layer selected from the group consisting of a titanium nitride layer, a copper layer, and an aluminum layer.
